(19) United States
(12) Patent Application Publication
(10) Pub. No.: US 2026/0146366 A1
(43) Pub. Date: May 28, 2026

(54) SILICON WAFER FOR EPITAXIAL GROWTH AND EPITAXIAL WAFER

(71) Applicant: Shin-Etsu Handotai Co., Ltd., Tokyo (JP)

(72) Inventors: Kosei SUGAWARA, Nishigo-mura (JP); Yuta TAMBA, Nishigo-mura (JP); Takahide ONAI, Nishigo-mura (JP)

(73) Assignee: Shin-Etsu Handotai Co., Ltd., Tokyo (JP)

(21) Appl. No.: 19/123,954

(22) PCT Filed: Sep. 21, 2023
(86) PCT No.: PCT/JP2023/034272

§ 371 Date: Apr. 24, 2025

(30) Foreign Application Priority Data
Nov. 10, 2022 (JP) 2022-180555

(51) Int. Cl. C30B 29/06; C30B 15/04; C30B 25/18

(52) U.S. Cl. CPC C30B 29/06; C30B 25/18; C30B 15/04

(57) ABSTRACT

A silicon wafer for epitaxial growth including a silicon single crystal, wherein the silicon single crystal is produced by a Czochralski method, an entire silicon single crystal is an N (Neutral) region so as not to contain a void and a dislocation cluster, size and density of oxygen precipitation nuclei are adjusted, and the oxygen precipitation nuclei with the size of 18 nm or more in the silicon wafer have the density of less than 5×10⁷/cm³. This provides the silicon wafer for epitaxial growth with inhibited defects and having extremely good surface layer quality.

### TECHNICAL FIELD

The present invention relates to a silicon wafer for epitaxial growth and an epitaxial wafer.

### BACKGROUND ART

Semiconductor devices (Logic, NAND, and DRAM) in which miniaturization and stacking have been advancing in recent years have two major issues.

One is a high-quality wafer having few or no defects near a surface to be a device operation region because an extremely small defect near the wafer surface can cause device failure.

The other is that a bulk micro defect (BMD) to be a gettering site for impurity metal needs to be sufficiently formed because metal contamination in the process causes decrease in a device yield.

Wafers satisfying the former requirement of defects near the wafer surface include: a few/no defect crystal PW produced with an N (Neutral) region having none of a V-rich region having COP derived from voids, an R-OSF region to generate oxidation-induced stacking fault during thermal oxidation, and a dislocation loop and a dislocation cluster derived from interstitial silicon; and an epitaxial wafer and an annealed wafer in which a no-defect layer is formed on a substrate.

Among these, the annealed wafer requires a long post-treatment time for forming the no-defect layer. Thus, the annealed wafer is unsuitable for large supply, and has a problem of tendency to raise a cost.

The epitaxial wafer needs an additional cost compared with the few/no defect crystal PW, but has a good defect level of the surface layer. Thus, the epitaxial wafers are widely used for leading Logic devices in which miniaturization is particularly advancing and the process becomes complex and long to cause a high process cost.

In the epitaxial wafer, the no-defect layer can be typically formed in the post-treatment in a relatively short time, and thereby use of a high-productive V-rich crystal grown at a higher speed than for the few/no defect crystal PW can compensate the additional cost for the EP reaction treatment.

Further, it is known that nitrogen doping is effective for increasing the bulk micro defect (BMD) to be a gettering site for impurity metal.

The nitrogen-doped V-rich crystal, however, may have problems of decrease in BMD density and EP defect formation in the outer peripheral portion of the wafer derived from the R-OSF region, and EP defect formation derived from plate-shaped or rod-shaped COP in doping nitrogen at high concentration.

Methods to avoid these problems include growing the crystal to be thicker than the product diameter and removing the portion corresponding to R-OSF by cylindrical polishing. This method, however, increases the polishing-process cost due to the polishing loss and increase in the process time.

Here, problems in producing the epitaxial wafer using a V-region substrate will be summarized. If an oxide film of voids on an inner wall cannot be removed or be made harmless in the pre-treatment of the EP reaction in a state of voids present on the substrate and exposed to the surface, this can become a cause of EP defects (SF) generation. In particular, nitrogen doping changes the shape of the voids from a regular octahedron to a plate or an elongated rod shape, and it becomes difficult to perform the removal or the harmlessness in the pre-treatment of the EP reaction, and thereby generation of EP defects derived from the voids increases. Furthermore, in a nitrogen-doped (110) and (551) substrates, voids deeply extending in a direction perpendicular to the wafer surface is formed, and thereby the removal or the harmlessness in the pre-treatment of the EP reaction becomes more difficult than using a (100) substrate. Thus, generation of the EP defects derived from the voids furthermore increases.

Another method is using a crystal with an N (Neutral) region so as not to contain R-OSF. As described later, even with the crystal with the N (Neutral) region so as not to contain R-OSF, oxygen precipitation nuclei present in the N (Neutral) region can be a generation cause of the EP defects. Thus, it has been difficult to achieve an extremely good EP surface layer defect level.

Next, importance of the bulk micro defect (BMD) to be a gettering site for impurity metal in order to inhibit that metal contamination in the process causes decrease in a yield of devices will be described.

Operation of MOSFET (source-drain current) needs to have an electrostatic capacity of a gate insulative film (=a relative permittivity of the insulative film×a gate area/a thickness of the insulative film) as a required amount. Reduction in the gate area due to a shortened gate length with the miniaturization is compensated by thinning the gate insulative film.

Thus, the gate insulative film in recent devices has an extremely small equivalent oxide film thickness (EOT) of about 0.5 nm, and thereby uniformity of the gate insulative film accounts for an important factor to reliability of device operation.

Accordingly, film thickness and film quality of the gate insulative film are uniformized by lowering temperature and shortening a time of various thermal treatment in the device process.

However, as a harmful effect of lowering the temperature and shortening the time of the device process, lowering the temperature and shortening the time decrease BMD formation in the device process to deteriorate gettering ability to impurity metal, leading to decrease in the device yield, in contrast to the conventional device process in which the bulk micro defect (BMD) to be a gettering site for impurity metal is sufficiently formed in the substrate.

Due to these problems, required for the leading low-temperature short-time device process is a wafer that easily forms the BMD compared with the conventional process, and that has high gettering ability even in the low-temperature short-time device process.

As for the above, the aforementioned epitaxial wafer using the crystal with an N (Neutral) region containing no R-OSF as the substrate has a problem of hardly forming the BMD compared with the epitaxial wafer with V-rich region as the substrate.

Next, these problems will be specifically described with the conventional art as examples.

Patent Document 1 discloses art that, when a V-region to generate void-type defects is used as the substrate, generation of the EP defects is inhibited to 0.02/cm² or less in maximum by setting the number of defects having opening size of the void-type defects appearing on the wafer surface of 20 nm or less to be 0.02/cm² or less in maximum. However, as many as 14 defects are present in terms of a 300-mm wafer, and it is difficult to further improve the defect level even by adjusting the void size or the density when using the V-region substrate having voids.

Patent Document 2 discloses an epitaxial wafer doped with nitrogen and carbon and using an N (Neutral) region substrate having no secondary defects such as voids and dislocation clusters. Patent Document 3 discloses art of doping with nitrogen and carbon to inhibit generation of the EP defects. However, the defect density is 0.05/cm² or less, which means as many as 35 defects in maximum in a 300-nm wafer. This is not a sufficient defect level for the leading Logic devices, which have the complex and long process, which have extremely few tolerable defects, and which have a high process cost. These prior arts have no clear advantage of using the N (Neutral) region substrate compared with the V-region substrate.

Patent Document 4 demonstrates that generation of the EP defects can be reduced to 2/wafer (0.0028/cm²) in maximum in a 300-mm wafer by using a silicon single crystal as the substrate with adjusted defect distribution of an N (Neutral) region in the entire crystal surface. Patent Document 4 also demonstrates effectiveness of using the silicon single crystal as the substrate with adjusted defect distribution of an N (Neutral) region in the entire crystal surface. However, generation source of the EP defects in the N (Neutral) region is unclear, and it is difficult to obtain stable quality of the EP surface layer and to further improve quality of the EP surface layer by only simply using the silicon substrate with the N (Neutral) region.

### CITATION LIST

### Patent Literature

Patent Document 1: JP 2004-43256 A
Patent Document 2: WO 2001/079593 A1
Patent Document 3: JP 2007-186376 A
Patent Document 4: JP 2019-206451 A

### SUMMARY OF INVENTION

### Technical Problem

An object of the present invention is to provide a silicon wafer for epitaxial growth having inhibited defects and extremely good quality of the surface layer.

### Solution to Problem

The present invention has been made to solve the above problems. The present invention provides a silicon wafer for epitaxial growth including a silicon single crystal, wherein the silicon single crystal is produced by a Czochralski method, an entire silicon single crystal is an N (Neutral) region so as not to contain a void and a dislocation cluster, size and density of oxygen precipitation nuclei are adjusted, and the oxygen precipitation nuclei with the size of 18 nm or more in the silicon wafer have the density of less than 5×10⁷/cm³.

With the silicon wafer for epitaxial growth as above, reduction in the density of the large-sized oxygen precipitation nuclei can inhibit defects in the epitaxial layer.

The oxygen precipitation nuclei with the size of 12 nm or more in the silicon wafer preferably have the average size of 18.5 nm or less, and the oxygen precipitation nuclei with the size of 12 nm or more preferably have the density of 4×10⁸/cm³ or less.

With the oxygen precipitation nuclei as above, the defects in the epitaxial layer can be furthermore inhibited.

Concentration of nitrogen doped in the silicon single crystal is preferably 2×10¹³ atom/cm³ to 30×10¹³ atom/cm³.

The silicon wafer as above has preferable gettering ability.

The silicon wafer having any one plane orientation of (100), (110), and (551) may be applied.

The defect generation can be inhibited with not only the (100), which has been conventionally used for the leading Logic devices, but also the (110) and the (551), which have been studied in recent years. The silicon wafer can contribute to development and quality improvement of the future leading logic devices.

Preferably it is an epitaxial wafer including an epitaxial layer formed on a surface of the silicon wafer for epitaxial growth, wherein the number of stacking faults and dislocations (EP-SF) in the epitaxial layer is 0.001/cm² or less.

The epitaxial wafer as above becomes the epitaxial wafer having extremely few stacking faults and dislocation (EP-SF), and suitable for extremely good leading devices.

BMD density in the silicon wafer after the above epitaxial wafer is subjected to an oxidative thermal treatment of 780° C. for 3 hours+1000° C. for 16 hours is preferably 1×10⁸/cm³ or more, and preferably satisfies the following relationship relative to the target BMD density,

$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$

The epitaxial wafer as above can yield the target BMD density of 1×10⁸/cm³ or more, and can achieve the BMD level equivalent to the V-region, even with the N-region, to yield the gettering ability sufficient as a gettering site for impurity metal.

### Advantageous Effects of Invention

As above, with the silicon wafer for epitaxial growth of the present invention, defects in the epitaxial layer can be inhibited by reducing the density of the large-sized oxygen precipitation nuclei. As a result, the epitaxial wafer having extremely good quality of the surface layer can be obtained, and the silicon wafer can also contribute to failure inhibition of the semiconductor devices in which miniaturization and stacking have been advancing.

In addition, setting the BMD density in the silicon wafer after the oxidative thermal treatment within an appropriate range can achieve the BMD level equivalent to the V-range, even with the N-region, and the gettering ability sufficient as a gettering site for impurity metal can be obtained. As a result, metal contamination in the process leading to deterioration of the yield of devices can be inhibited.

Further, the good quality as above can be obtained regardless of the plane orientation in the wafer, and the silicon wafer can contribute to development and ability improvement of the future leading logic devices.

### BRIEF DESCRIPTION OF DRAWINGS

FIG. 1 is a view illustrating one embodiment of a producing apparatus of a silicon single crystal by a Czochralski method usable in the present invention.

### DESCRIPTION OF EMBODIMENTS

As noted above, there has been a demand for development of the silicon wafer for epitaxial growth having inhibited defects and extremely good quality of the surface layer.

As for the above, the present inventors have firstly earnestly researched and studied the generation source of defects to be the generation factor of the EP defects even in the N (Neutral) region, as described in Patent Document 4.

As a result, it has been revealed that, as for the generation source of defects to be the generation factor of the EP defects in the N (Neutral) region, oxygen precipitation nuclei with size larger than the predetermined size present in the N (Neutral) region form the stacking fault and dislocation (EP-SF) at a certain possibility.

More specifically, the oxygen precipitation nuclei in the substrate with the as-grown N (Neutral) region (Void (COP)-free) and the stacking fault and dislocation (EP-SF) have a relationship:

$$Number of EP defects = A \cdot exp ( Average size of precipitation nuclei / B ) .$$

It has been found that setting the number of oxygen precipitation nuclei with 18 nm or more to less than 5×10⁷/cm³ in the as-grown state, more preferably setting oxygen precipitation nuclei with 12 nm or more to have the average size of 18.5 nm or less and the density of 4×10⁸/cm³ or less, can reduce the number of EP defects to 0.001/cm² or less (0.7/wafer or less in terms of a 300-mm wafer), which reduces generation of stacking fault and dislocation (EP-SF) to less than 1 in average in a 300-mm wafer and which is extremely good level.

In this correlation formula, A corresponds to a frequency factor, which is a parameter proportional to the density of the oxygen precipitation nuclei. B is a process parameter that affects tolerance of the oxygen precipitation nuclei in the process for forming the epitaxial layer.

Note that the density and size of the oxygen precipitation nuclei in such an as-grown state can be controlled only when the N (Neutral) region is used as the substrate. When the V-region substrate is used, the size and the density of the oxygen precipitation nuclei strongly depend on the nitrogen concentration, which cannot be controlled.

The epitaxial wafer using the crystal of the N (Neutral) region as the substrate has a problem of hardly forming the BMD compared with the epitaxial wafer using the V-rich region as the substrate. However, it has also been found that the BMD level equivalent to the case of using the V-region substrate can be achieved by satisfying:

$$the target BMD density \leq 9.6875 \times {10}^{8} \{ exp ( Ini . Oi [ ppma - {ASTM}^{′} 79 ] - 21.99 - 5.35 ) \} \hat{} 0.3961 ,$$

in the case of doping with nitrogen at 2×10¹³ to 3×10¹⁴ atoms/cm³, in the crystal with the controlled density and with the controlled size of the precipitation nuclei of the neutral region so that the substrate oxygen concentration is larger than that in the case of the V-region substrate by +5.35 [ppma-ASTM'79].

Here, when the V-rich region is used as the substrate, the target BMD density satisfies the target BMD density≤9.6875×10⁸ {exp (Ini. Oi[ppma-ASTM'79]-21.99)}\hat{ }0.3961.

Further, the epitaxial wafer obtained in the present invention and using the substrate with the controlled density and with the controlled size of the oxygen precipitation nuclei with the N (Neutral) region in the as-grown state can achieve both the extremely good quality of the surface layer and the BMD quality with not only the (100) epitaxial wafer, which is conventionally used for the leading Logic devices, but also the nitrogen-doped (110) and (551) substrates without limitation of the wafer plane orientation.

As above, the present invention has been completed by the earnest study by the inventors. The present invention enables to produce the epitaxial wafer that achieves the extremely good defect level of the EP surface layer regardless of the wafer plane orientation and that also has high gettering ability by controlling the density and the size of the oxygen precipitation nuclei in the as-grown state in the epitaxial wafer using the few/no defect crystal produced with the nitrogen-doped N (Neutral) region as the substrate.

Use of the present invention enables us to produce the epitaxial wafer having reduced EP defects leading to device failure and having extremely good defect level of the EP surface layer, and enables to produce the leading Logic devices, which have the complex and long process, which have extremely few tolerable defects, and which have a high process cost, with a high yield.

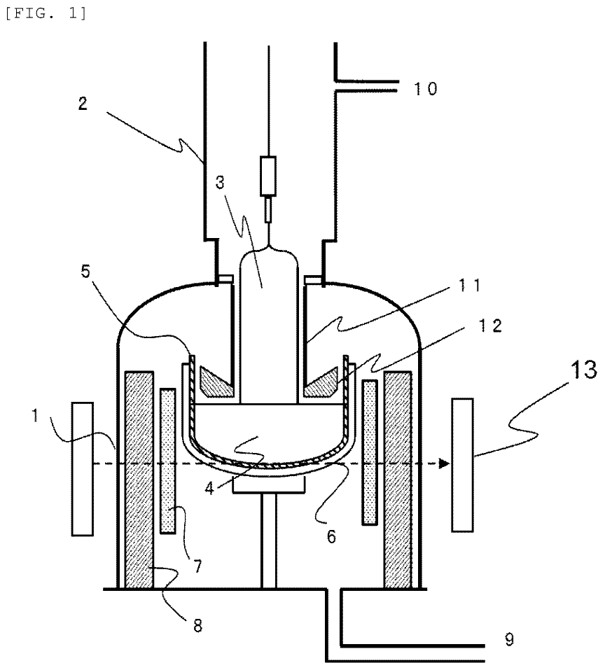

Hereinafter, one embodiment of the present invention will be described with reference to FIG. 1.

Used for producing the silicon single crystal in the present invention is a producing apparatus for the silicon single crystal, as illustrated in FIG. 1, for example, that can grow a silicon single crystal (hereinafter, which may be simply referred to as “single crystal” or “crystal”) by the Czochralski method under a condition such that the entire surface of the crystal becomes the N-region. The producing apparatus for the silicon single crystal as above will be described with reference to FIG. 1, but the single-crystal producing apparatus usable in the present invention is not limited thereto.

The appearance of the producing apparatus for the silicon single crystal illustrated in FIG. 1 is constituted with a main chamber 1 and a pulling chamber 2 communicated therewith. Inside the main chamber 1, a graphite crucible 6 and a quartz crucible 5 are arranged. A heater 7 is provided so as to surround the graphite crucible 6 and the quartz crucible 5, and a raw material silicon polycrystal contained in the quartz crucible 5 is melted with the heater 7 to form a raw material melted liquid 4. A thermal insulator 8 is provided to prevent an effect of radiant heat from the heater 7 on the main chamber 1, etc.

On a melted liquid surface of the raw material melted liquid 4, a heat-shielding body 12 is arranged so as to face the melted liquid surface with a predetermined distance, and shields the radiant heat from the melted liquid surface of the raw material melted liquid 4. A seed crystal is immersed in this crucible, and then a rod-shaped single-crystal rod 3 is pulled up from the raw material melted liquid 4. The crucible can be raised or lowered in a direction of crystal growth axis, and a height of the melted liquid surface of the raw material melted liquid 4 is retained at an approximate level by raising the crucible during growth so as to compensate lowering of the liquid level of the raw material melted liquid 4 reduced by proceeding of the growth of the single crystal.

Further, inert gas such as argon gas as a purge gas is introduced during growth of the single crystal through a gas-introducing port 10. The inert gas is passed between the single-crystal rod 3 with being pulled up and a gas straightening cylinder 11, then passed between the heat-shielding body 12 and the melted liquid surface of the raw material melted liquid 4, and discharged through a gas-discharging port 9. A pressure in the chamber during the pulling is controlled by controlling a flow rate of the introduced gas and an amount of discharging gas with a pump or a valve.

In growing the crystal by the Czochralski method, a magnetic field may be applied with a magnetic-field applying apparatus 13. The method of applying a magnetic field is called “MCZ method”.

In the present invention, in growing the single crystal by the Czochralski method with the single-crystal pulling apparatus as above, the defect region of the grown single crystal can be entirely the N-region by pulling the crystal with controlling a ratio V/G between a pulling velocity V [mm/min] and a temperature gradient G [° C./mm] of the solid-liquid interface in the axial direction. The size and the density of the oxygen precipitation nuclei in the single crystal can be controlled by adjusting oxygen concentration and nitrogen concentration in the growing single crystal and thermal history of the crystal. For example, the oxygen concentration can be controlled by adjusting a rotation rate of the crucible and convection of the raw material melted liquid. The nitrogen concentration can be controlled by a doping amount of N into the raw material melted liquid. The thermal history can be controlled by the pulling velocity of the crystal and structure in the furnace.

The silicon wafer for epitaxial growth of one embodiment of the present invention is a silicon wafer produced from a silicon single crystal, wherein the silicon single crystal is produced by an MCZ method of a Czochralski method, an entire silicon single crystal is an N (Neutral) region so as not to contain a void and a dislocation cluster, size and density of oxygen precipitation nuclei are adjusted, and the oxygen precipitation nuclei with the size of 18 nm or more in the silicon wafer have the density of less than 5×10⁷/cm³, more preferably the oxygen precipitation nuclei with the size of 12 nm or more have the average size of 18.5 nm or less, and the oxygen precipitation nuclei with the size of 12 nm or more have the density of 4×10⁸/cm³ or less.

As above, generation of defects in the epitaxial layer can be inhibited by reducing the density of the large-sized oxygen precipitation nuclei. As for the oxygen precipitation nuclei in the silicon wafer, an upper limit of the size with 18 nm or more is not particularly limited, and may be 40 nm or less, for example. A lower limit of the density of the nuclei with the size of 18 nm or more is not particularly limited, and may be 1×10⁶/cm³ or more, for example. An upper limit of the size with 12 nm or more is not particularly limited, and may be 40 nm or less, for example. A lower limit of the average size of the size with 12 nm or more is not particularly limited, and may be 12 nm or more, for example. A lower limit of the density of the nuclei with the size of 12 nm or more is not particularly limited, and may be 1×10⁶/cm³ or more, for example.

Concentration of nitrogen doped in the silicon single crystal is preferably 2×10¹³ atom/cm³ to 30×10¹³ atom/cm³.

The silicon wafer as above has sufficient gettering ability, and can be suitably applied for the leading devices.

Even when the plane orientation of the silicon wafer is any one of (100), (110), and (551), the size and the density of the oxygen precipitation nuclei in the entire surface of the N (Neutral) region of the present invention can be controlled.

The generation of defects can be inhibited with not only the (100), which has been conventionally used for the leading Logic devices, but also the (110) and (551), which have been studied in recent years. This can contribute to development and ability improvement of the future leading logic devices.

The present invention is an epitaxial wafer including an epitaxial layer formed on a surface of the silicon wafer for epitaxial growth, wherein the number of stacking faults and dislocations (EP-SF) in the epitaxial layer is 0.001/cm² or less.

The silicon wafer as above is the extremely good epitaxial wafer having extremely few stacking faults and dislocations (EP-SF), and thereby sufficiently durable in the leading device production. A lower limit of the stacking faults and dislocations (EP-SF) in the epitaxial layer is not particularly limited, and may be 0/cm² or more, for example.

BMD density in a silicon wafer after the epitaxial wafer is subjected to an oxidative thermal treatment of 780° C. for 3 hours+1000° C. for 16 hours is 1×10⁸/cm³ or more, and satisfies the following relationship relative to the target BMD density,

$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$

The epitaxial wafer can yield the target BMD density of 1×10⁸/cm³ or more, and can achieve the BMD level equivalent to the V-region even with the N-region to obtain the gettering ability sufficient as a gettering site for impurity metal. An upper limit of the BMD density in the silicon wafer after the oxidative thermal treatment is not particularly limited, and may be 10×10⁸/cm³ or less, for example. The target BMD density is not particularly limited, and may be 1×10⁸/cm³ or more and 10×10⁸/cm³ or less, for example.

To achieve the target BMD when the V-rich region is used as the substrate, the target BMD density of 1×10⁸/cm³ or more is obtained by satisfying the BMD density≤9.6875× 10⁸ {exp (Ini.Oi[ppma-ASTM'79]-21.99)}\hat{ }0.3961.

The density and the size of the oxygen precipitation nuclei are desirably evaluated with a laser scattering tomography (LST) inspection apparatus. For example, LST-2500, available from Semilab Japan KK, and MO441, available from MITSUI MINING & SMELTING CO., LTD., can be used.

Here, MO441 (available from MITSUI MINING & SMELTING CO., LTD.) has a detection sensitivity of 18 nm or more. When the density of the oxygen precipitation nuclei to be detected is less than 5×10⁷/cm³, the EP defects can be approximately inhibited. This detection is, however, detection evaluation with the size near the limit of the detection sensitivity of MO441, and thereby the size is desirably detected and evaluated with higher sensitivity. For example, LST-2500, available from Semilab Japan KK, enables detection and evaluation with high sensitivity of a detection sensitivity of 12 nm or more. When the oxygen precipitation nuclei are detected and evaluated with the high sensitivity with LST-2500, available from Semilab Japan KK, the EP defects can be more certainly inhibited and controlled by setting the oxygen precipitation nuclei with 12 nm or more and the average size of 18.5 nm or less and 12 nm or more to have the density of 4×10⁸/cm³ or less.

With detection and evaluation of the precipitation nuclei with the higher sensitivity and good accuracy, the frequency factor A, which is a parameter proportional to the density of the oxygen precipitation nuclei, and the process parameter B, which affects tolerance of the precipitation nuclei in the process for forming the epitaxial layer, in Number of EP defects=A·exp (Average size of precipitation nuclei/B) are more accurately determined, and the EP defects can be more certainly inhibited and controlled.

### EXAMPLES

Hereinafter, the description will be specifically made with Examples and Comparative Examples of the present invention, but the present invention is not limited thereto.

### Comparative Example 1

In a 32-inch (diameter: 812.8 mm) crucible, 410 kg of a silicon raw material was melted. A transverse magnetic field at a center magnetic-field intensity of 4000 G was applied by an MCZ method, and a 300-mm silicon single crystal with an axial orientation <100> was grown (without nitrogen doping) while controlling V/G so that the entire surface of the crystal was an N (Neutral) region. A wafer was cut from the silicon single crystal produced as above, and subjected to wrapping, rounding, and polishing to produce a plurality of silicon wafers for epitaxial growth with a plane orientation (100).

Then, the density and the size of oxygen precipitation nuclei present in this silicon wafer for epitaxial growth in the as-grown state were evaluated with LST-2500, available from Semilab Japan KK, a laser scattering tomography (LST) inspection apparatus. The results were as follows:

In the center portion of the wafer, R0-50 mm, the density of oxygen precipitation nuclei with the size of 18 nm or more was 7.5×10⁷/cm³, the density of oxygen precipitation nuclei with 12 nm or more was 7.0×10⁸/cm³, and the average size was 19.2 nm;

In R60-120 mm, the density of oxygen precipitation nuclei with the size of 18 nm or more was 4.2×10⁷/cm³, the density of oxygen precipitation nuclei with 12 nm or more was 4.2×10⁸/cm³, and the average size was 18.3 nm; and

In R130-150 mm, the density of oxygen precipitation nuclei with the size of 18 nm or more was 5.5×10⁷/cm³, the density of oxygen precipitation nuclei with 12 nm or more was 8.0×10⁸/cm³, and the average size was 19.0 nm.

By using these silicon wafers for epitaxial growth, an epitaxial layers with 4 μm were formed at 1130° C. to produce 25 epitaxial wafers. Defects on the obtained epitaxial wafers were evaluated by using SP3, available from KLA Tencor, with 32-nm UP sensitivity of “Oblique mode”.

As a result, in each wafer, the average density of EP defects was 0.0019/cm² in R0-50 mm, 0.0010/wf in R60-120 mm, and 0.0021/cm² in R130-R150 mm, and the number of EP defects in the entire surface of the 300-mm wafer was 0.99/wf.

In this time, oxygen concentration in the silicon single crystal was 25.2 [ppma-ASTM'79], and the BMD density after EP and after an oxidative thermal treatment of 780° C. for 3 hours+1000° C. for 16 hours was 4.1×10⁸ [/cm³].

### Comparative Example 2

Silicon wafers for epitaxial growth and epitaxial wafers were produced under the same condition as in Comparative Example 1 except that the wafer was doped with nitrogen at a concentration range of 4×10¹³ to 3×10¹⁴ atoms/cm³.

The density and the size of oxygen precipitation nuclei present in the as-grown state were evaluated with the LST inspection apparatus, similarly to Comparative Example 1. The results were as follows:

In the center portion of the wafer, R0-50 mm, the density of oxygen precipitation nuclei with the size of 18 nm or more was 9.2×10⁷/cm³, the density of oxygen precipitation nuclei with 12 nm or more was 9.0×10⁸/cm³, and the average size was 21.0 nm;

In R60-120 mm, the density of oxygen precipitation nuclei with the size of 18 nm or more was 5×10⁷/cm³, the density of oxygen precipitation nuclei with 12 nm or more was 5×10⁸/cm³, and the average size was 18.7 nm; and

In R130-150 mm, the density of oxygen precipitation nuclei with the size of 18 nm or more was 1.1×10⁸/cm³, the density of oxygen precipitation nuclei with 12 nm or more was 1.0×10⁹/cm³, and the average size was 22.0 nm.

In each of the epitaxial wafers, the average density of EP defects was 0.0029/cm² in R0-50 mm, 0.0013/wf in R60-120 mm, and 0.0036/cm² in R130-R150 mm, and the number of EP defects in the entire surface of the 300-mm wafer was 1.46/wf.

In this time, the oxygen concentration in the silicon single crystal was 25.5 [ppma-ASTM'79], and the BMD density after EP and after an oxidative thermal treatment of 780° C. for 3 hours+1000° C. for 16 hours was 4.7×10⁸ [/cm³].

### Example 1

Silicon wafers for epitaxial growth and epitaxial wafers were produced under the same condition as in Comparative Example 1 except that the density and the size of the oxygen precipitation nuclei were adjusted by regulating the pulling velocity.

The density and the size of oxygen precipitation nuclei present in the as-grown state were evaluated with the LST inspection apparatus, similarly to Comparative Examples 1 and 2. The results were as follows:

In the center portion of the wafer, R0-50 mm, the density of oxygen precipitation nuclei with the size of 18 nm or more was 3.8×10⁷/cm³, the density of oxygen precipitation nuclei with 12 nm or more was 3.6×10⁸/cm³, and the average size was 18.2 nm;

In R60-120 mm, the density of oxygen precipitation nuclei with the size of 18 nm or more was 2.9×10⁷/cm³, the density of oxygen precipitation nuclei with 12 nm or more was 2.6×10⁸/cm³, and the average size was 18.1 nm; and

In R130-150 mm, the density of oxygen precipitation nuclei with the size of 18 nm or more was 3.0×10⁷/cm³, the density of oxygen precipitation nuclei with 12 nm or more was 2.7×10⁸/cm³, and the average size was 18.3 nm.

In each of the epitaxial wafers, the average density of EP defects was 0.0009/cm² in R0-50 mm, 0.0006/wf in R60-120 mm, and 0.0007/cm² in R130-R150 mm, and the number of EP defects in the entire surface of the 300-mm wafer was 0.46/wf.

In this time, so that the target BMD density after EP and after an oxidative thermal treatment of 780° C. for 3 hours+1000° C. for 16 hours was 4×10⁸/cm³ or more, it was calculated from the relationship of [Formula A] that the oxygen concentration in the silicon single crystal was required to be 25.1 [ppma-ASTM'79] or more. The actual oxygen concentration was 25.2 [ppma-ASTM'79], and the BMD density was 4.2×10⁸ [/cm³].

$$Target BMD density \leq 9.6875 \times {10}^{8} \{ exp ( Ini . Oi [ ppma - {ASTM}^{′} 79 ] - 21.99 - 5.35 ) \} \hat{} 0.3961 . \qquad [ Formula A ]$$

### Example 2

Silicon wafers for epitaxial growth and epitaxial wafers were produced under the same condition as in Comparative Example 2 except that the density and the size of the oxygen precipitation nuclei were adjusted by regulating the pulling velocity.

The density and the size of oxygen precipitation nuclei present in the as-grown state were evaluated with the LST inspection apparatus, similarly to Comparative Examples 1 and 2. The results were as follows:

In the center portion of the wafer, R0-50 mm, the density of oxygen precipitation nuclei with the size of 18 nm or more was 4.0×10⁷/cm³, the density of oxygen precipitation nuclei with 12 nm or more was 3.8×10⁸/cm³, and the average size was 18.4 nm;

In R60-120 mm, the density of oxygen precipitation nuclei with the size of 18 nm or more was 3.1×10⁷/cm³, the density of oxygen precipitation nuclei with 12 nm or more was 2.9×10⁸/cm³, and the average size was 18.2 nm; and

In R130-150 mm, the density of oxygen precipitation nuclei with the size of 18 nm or more was 2.8×10⁷/cm³, the density of oxygen precipitation nuclei with 12 nm or more was 2.5×10⁸/cm³, and the average size was 18.4 nm.

In each of the epitaxial wafers, the average density of EP defects was 0.0009/cm² in R0-50 mm, 0.0007/wf in R60-120 mm, and 0.0006/cm² in R130-R150 mm, and the number of EP defects in the entire surface of the 300-mm wafer was 0.49/wf.

In this time, so that the target BMD density after EP and after an oxidative thermal treatment of 780° C. for 3 hours+1000° C. for 16 hours was 4×10⁸/cm³ or more, it was calculated from the relationship of [Formula A] that the oxygen concentration in the silicon single crystal was required to be 25.1 [ppma-ASTM'79] or more. The actual oxygen concentration was 25.4 [ppma-ASTM'79], and the BMD density was 4.5×10⁸ [/cm³].

### Example 3

Silicon wafers for epitaxial growth with a plane orientation (110) or (551) and epitaxial wafers were produced under the same condition as in Example 2 except that the axial orientation of the growing crystal was <110> or <551>.

The density and the size of oxygen precipitation nuclei present in the as-grown state in the silicon wafer for epitaxial growth produced from the 300-mm silicon single crystal with an axial orientation <110> were evaluated with the LST inspection apparatus, similarly to Example 2.

In the center portion of the wafer, R0-50 mm, the density of oxygen precipitation nuclei with the size of 18 nm or more was 3.9×10⁷/cm³, the density of oxygen precipitation nuclei with 12 nm or more was 3.7×10⁸/cm³, and the average size was 18.4 nm;

In R60-120 mm, the density of oxygen precipitation nuclei with the size of 18 nm or more was 3.3×10⁷/cm³, the density of oxygen precipitation nuclei with 12 nm or more was 3.0×10⁸/cm³, and the average size was 18.2 nm; and

In R130-150 mm, the density of oxygen precipitation nuclei with the size of 18 nm or more was 2.5×10⁷/cm³, the density of oxygen precipitation nuclei with 12 nm or more was 2.4×10⁸/cm³, and the average size was 18.4 nm.

In the silicon wafer for epitaxial growth produced from the silicon single crystal with an axial orientation <511>, the cleavage plane was unobtainable, and the LST evaluation could not be performed.

In each of the epitaxial wafers, the average density of EP defects was equivalent to that in Example 2 with both the plane orientations (110) and (551).

In this time, so that the target BMD density after EP and after an oxidative thermal treatment of 780° C. for 3 hours+1000° C. for 16 hours was 4×10⁸/cm³ or more, it was calculated from the relationship of [Formula A] that the oxygen concentration in the silicon single crystal was required to be 25.1 [ppma-ASTM'79] or more. The actual oxygen concentration was 25.1 [ppma-ASTM'79] with both the silicon single crystals with the axial orientations <110> and <551>. The BMD density in the silicon wafer for epitaxial growth produced from the 300-mm silicon single crystal with the axial orientation <110> was 4.0×10⁸ [/cm³].

In the silicon wafer for epitaxial growth produced from the silicon single crystal with an axial orientation <511>, the cleavage plane was unobtainable, and the LST evaluation could not be performed.

Table 1 shows each condition in Examples and Comparative Examples, and the density and the average size of the oxygen precipitation nuclei, the EP defect density, and the total number of the EP defects on the epitaxial wafer produced under each condition.

TABLE 1

| | | | | | Average | | |
|---|---|---|---|---|---|---|---|
| | | | Density of | Density of | size of | | |
| | | | precipitation | precipitation | precipitation | | Total |
| | | Radius | nuclei with | nuclei with | nuclei with | EP defect | number of |
| | | position | 18 nm or more | 12 nm or more | 12 nm or more | density | EP defects |
| | | [mm] | [/cm³] | [/cm³] | [nm] | [/cm²] | [/wf] |
| Nitrogen undoped | Comparative | R0-50 | 7.5E+07 | 7.0E+08 | 19.2 | 0.0019 | 0.99 |
| | Example 1 | R60-120 | 4.2E+07 | 4.2E+08 | 18.3 | 0.0010 | |
| | | R130-R150 | 5.5E+07 | 8.0E+08 | 19.0 | 0.0021 | |
| Nitrogen doped | Comparative | R0-50 | 9.2E+07 | 9.0E+08 | 21.0 | 0.0029 | 1.46 |
| 4E13-3E14 atoms/cm³ | Example 2 | R60-120 | 5.0E+07 | 5.0E+08 | 18.7 | 0.0013 | |
| | | R130-R150 | 1.1E+08 | 1.0E+09 | 22.0 | 0.0036 | |
| Nitrogen undoped | Example 1 | R0-50 | 3.8E+07 | 3.6E+08 | 18.2 | 0.0009 | 0.46 |
| Controlled | | R60-120 | 2.9E+07 | 2.6E+08 | 18.1 | 0.0006 | |
| precipitation | | R130-R150 | 3.0E+07 | 2.7E+08 | 18.3 | 0.0007 | |
| nuclei and size | | | | | | | |
| Nitrogen doped | Example 2 | R0-50 | 4.0E+07 | 3.8E+08 | 18.4 | 0.0009 | 0.49 |
| 4E13-2E14 atoms/cm³ | Plane | R60-120 | 3.1E+07 | 2.9E+08 | 18.2 | 0.0007 | |
| Controlled | orientation | R130-R150 | 2.8E+07 | 2.5E+08 | 18.4 | 0.0006 | |
| precipitation | (100) | | | | | | |
| nuclei and size | Example 3 | R0-50 | 3.9E+07 | 3.7E+08 | 18.4 | 0.0009 | 0.49 |
| | Plane | R60-120 | 3.3E+07 | 3.0E+08 | 18.2 | 0.0007 | |
| | orientation | R130-R150 | 2.5E+07 | 2.4E+08 | 18.4 | 0.0006 | |
| | (110) | | | | | | |
| | Plane | R0-50 | unmeasurable | unmeasurable | unmeasurable | 0.0009 | 0.49 |
| | orientation | R60-120 | unmeasurable | unmeasurable | unmeasurable | 0.0007 | |
| | (551) | R130-R150 | unmeasurable | unmeasurable | unmeasurable | 0.0006 | |

### [Results]

As obvious from Table 1, Examples 1, 2, and 3 exhibited smaller values of both the EP defect density and the total number of the EP defects, which were excellent, than Comparative Examples 1 and 2. The EP defect density in both Comparative Examples 1 and 2 was 0.001/cm² or more. In contrast, the EP defect density in all Examples 1, 2, and 3 was less than 0.001/cm². The total number of the EP defects in both Comparative Examples 1 and 2 was 0.5/wf or more. In contrast, the total number of the EP defects in all Examples 1, 2, and 3 was less than 0.5/wf.

From the above results, it has been found that the number of the EP defects and the as-grown precipitation nuclei have the relationship of the number of the EP defects=A·exp (Average size of precipitation nuclei/B) in producing the epitaxial wafer using the N (Neutral) region (Void (COP)-free) substrate. A=a×the density of precipitation nuclei with 12 nm or more [/cm³]. From Comparative Examples 1 and 2 and Example 1, a=2.80×10⁻¹⁰, and B=10.

As above, the relationship between the number of the EP defects and the as-grown precipitation nuclei is obvious in producing the epitaxial wafer using the N (Neutral) region (Void (COP)-free) substrate. The epitaxial wafer having extremely good EP surface layer quality in which generation of the EP defects is inhibited to 0.001/cm² can be obtained by setting the number of the precipitation nuclei in the wafer to be less than 5×10⁷/cm³ with the size of 18 nm or more, more preferably setting the average size with 12 nm or more to be 18.5 nm or less and the density of the precipitation nuclei with 12 nm or more to 4×10⁸/cm³ or less. The effect of the present invention can be obtained regardless of the wafer plane orientation.

As for the BMD density of the epitaxial wafer after the oxidative thermal treatment of 780° C. for 3 hours+1000° C. for 16 hours, the epitaxial wafer having in-plane uniform BMD distribution with the BMD density of 1×10⁸/cm³ or more and having high gettering ability can be obtained by setting the target BMD density to satisfy

$$the target BMD density \leq 9.6875 \times {10}^{8} \{ exp ( Ini . Oi [ ppma - {ASTM}^{′} 79 ] - 21.99 - 5.35 ) \} \hat{} 0.3961 ;$$

(In a case of V-rich:

$$the target BMD density \leq 9.6875 \times {10}^{8} \{ exp ( Ini . Oi [ ppma - {ASTM}^{′} 79 ] - 21 \text{.99} ) \} \hat{} 0.3961 . )$$

As above, the present invention enables to produce the epitaxial wafer with inhibited EP defects leading to device failure, having an extremely good level of EP surface layer defect, and having high gettering ability.

The present invention enables to produce the leading Logic devices, which have the complex and long process, which have extremely few tolerable defects, and which have a high process cost, with a high yield.

The present invention includes the following embodiments.

[1]: A silicon wafer for epitaxial growth, comprising a silicon single crystal, wherein
the silicon single crystal is produced by a Czochralski method,
an entire silicon single crystal is an N (Neutral) region so as not to contain a void and a dislocation cluster,
size and density of oxygen precipitation nuclei are adjusted, and
the oxygen precipitation nuclei with the size of 18 nm or more in the silicon wafer have the density of less than 5×10⁷/cm³.
   [2]: The silicon wafer for epitaxial growth according to [1], wherein the oxygen precipitation nuclei with the size of 12 nm or more have the average size of 18.5 nm or less, and the oxygen precipitation nuclei with the size of 12 nm or more have the density of 4×10⁸/cm³ or less.
   [3]: The silicon wafer for epitaxial growth according to [1] or [2], wherein concentration of nitrogen doped in the silicon single crystal is 2×10¹³ atom/cm³ to 30×10¹³ atom/cm³.
   [4]: The silicon wafer for epitaxial growth according to [1], [2] or [3], wherein the silicon wafer has any one plane orientation of (100), (110), and (551).
   [5]: An epitaxial wafer, comprising:
the silicon wafer for epitaxial growth according to any one of [1] to [4]; and
an epitaxial layer formed on a surface of the silicon wafer for epitaxial growth,
wherein the number of stacking faults and dislocations (EP-SF) in the epitaxial layer is 0.001/cm² or less.
   [6]: The epitaxial wafer according to [5], wherein

BMD density in the silicon wafer after the epitaxial wafer is subjected to an oxidative thermal treatment of 780° C. for 3 hours+1000° C. for 16 hours is 1×10⁸/cm³ or more, and satisfies the following relationship relative to the target BMD density,

$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A silicon wafer for epitaxial growth, comprising a silicon single crystal, wherein
the silicon single crystal is produced by a Czochralski method,
an entire silicon single crystal is an N (Neutral) region so as not to contain a void and a dislocation cluster,
size and density of oxygen precipitation nuclei are adjusted, and
the oxygen precipitation nuclei with the size of 18 nm or more in the silicon wafer have the density of less than 5×10⁷/cm³.

2. The silicon wafer for epitaxial growth according to claim 1, wherein the oxygen precipitation nuclei with the size of 12 nm or more have the average size of 18.5 nm or less, and the oxygen precipitation nuclei with the size of 12 nm or more have the density of 4×10⁸/cm³ or less.

3. The silicon wafer for epitaxial growth according to claim 1, wherein concentration of nitrogen doped in the silicon single crystal is 2×10¹³ atom/cm³ to 30×10¹³ atom/cm³.

4. The silicon wafer for epitaxial growth according to claim 1, wherein the silicon wafer has any one plane orientation of (100), (110), and (551).

5. An epitaxial wafer, comprising:
the silicon wafer for epitaxial growth according to claim 1; and
an epitaxial layer formed on a surface of the silicon wafer for epitaxial growth,
wherein the number of stacking faults and dislocations (EP-SF) in the epitaxial layer is 0.001/cm² or less.

6. (canceled)

7. An epitaxial wafer, comprising:
the silicon wafer for epitaxial growth according to claim 2; and
an epitaxial layer formed on a surface of the silicon wafer for epitaxial growth,
wherein the number of stacking faults and dislocations (EP-SF) in the epitaxial layer is 0.001/cm² or less.

8. An epitaxial wafer, comprising:
the silicon wafer for epitaxial growth according to claim 3; and
an epitaxial layer formed on a surface of the silicon wafer for epitaxial growth,
wherein the number of stacking faults and dislocations (EP-SF) in the epitaxial layer is 0.001/cm² or less.

9. An epitaxial wafer, comprising:
the silicon wafer for epitaxial growth according to claim 4; and
an epitaxial layer formed on a surface of the silicon wafer for epitaxial growth,
wherein the number of stacking faults and dislocations (EP-SF) in the epitaxial layer is 0.001/cm² or less.

10. The epitaxial wafer according to claim 5, wherein
BMD density in the silicon wafer after the epitaxial wafer is subjected to an oxidative thermal treatment of 780° C. for 3 hours+1000° C. for 16 hours is 1×10⁸/cm³ or more, and satisfies the following relationship relative to the target BMD density,
$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$

11. The epitaxial wafer according to claim 7, wherein
BMD density in the silicon wafer after the epitaxial wafer is subjected to an oxidative thermal treatment of 780° C. for 3 hours+1000° C. for 16 hours is 1×10⁸/cm³ or more, and satisfies the following relationship relative to the target BMD density,
$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$

12. The epitaxial wafer according to claim 8, wherein
BMD density in the silicon wafer after the epitaxial wafer is subjected to an oxidative thermal treatment of 780° C. for 3 hours+1000° C. for 16 hours is 1×10⁸/cm³ or more, and satisfies the following relationship relative to the target BMD density,
$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$

13. The epitaxial wafer according to claim 9, wherein
BMD density in the silicon wafer after the epitaxial wafer is subjected to an oxidative thermal treatment of 780° C. for 3 hours+1000° C. for 16 hours is 1×10⁸/cm³ or more, and satisfies the following relationship relative to the target BMD density,
$$the target BMD density \leq 9.6875 \times {10}^{8} \{ exp ( Ini . Oi [ ppma - {ASTM}^{′} 79 ] - 21.99 - 5.35 ) \} \hat{} 0.3961 .$$
